(19) United States
(12) Patent Application Publication
(10) Pub. No.: US 2017/0089511 A1
(43) Pub. Date: Mar. 30, 2017

(54) WALL-HANG APPARATUS OF DISPLAY DEVICE, AND DISPLAY DEVICE

(71) Applicants: LE HOLDINGS (BEIJING) CO., LTD., Beijing (CN); LE SHI ZHI XIN ELECTRONIC TECHNOLOGY (TIAN JIN) LIMITED, Tianjin (CN)

(72) Inventors: Cong ZHANG, Tianjin (CN); Shiming QING, Tianjin (CN); Feng SUN, Tianjin (CN)

(21) Appl. No.: 15/221,150

(22) Filed: Jul. 27, 2016

Related U.S. Application Data
(63) Continuation of application No. PCT/CN2016/081946, filed on May 13, 2016.

(30) Foreign Application Priority Data
Sep. 28, 2015 (CN) 201520757122.5

(51) Int. Cl. F16M 13/02; H05K 7/18; F16B 45/00

(52) U.S. Cl. CPC F16M 13/02; F16B 45/00; H05K 7/186

(57) ABSTRACT

The disclosure provides a wall-hang apparatus of a display device, and a display device. The wall-hang apparatus of a display device includes: a wall fixture configured to be fixed to a wall, display device fixtures configured to be fixed to a display device body, and hang pieces, wherein the wall fixture includes first hang hooks with a notch facing upward; and the hang pieces are fixed to the display device fixtures, and include first stop blocks hung on the first hang hooks, and second stop blocks located below the first stop blocks. With the wall-hang apparatus of a display device according to the disclosure, the reliability of hanging the display device on a wall securely can be improved.

### CROSS-REFERENCE TO RELATED APPLICATIONS

This application is a continuation International Application No, PCT/CN2016/081946, filed on May 13, 2016, which claims priority to Chinese Patent Application No. 201520757122.5, filed on Sep. 28, 2015, both of which are hereby incorporated by reference in their entireties.

### FIELD

The present disclosure relates to the field of installing a display device, and particularly to a wall-hang apparatus of a display device, and a display device.

### BACKGROUND

A hang bracket of a TV set is a peripheral apparatus of the TV set, which is specifically designed to hang a flat screen TV set, a liquid crystal TV set, etc., on a wall, and widely applied at home, in an office, a meeting room, an exhibition hall, a hotel, an airport, a railway station, a hospital, a bus stop, a shopping mall, and other places.

At preset, the TV set is generally installed on the hang bracket simply by hanging the TV set on the hang bracket, but if the TV set is touched unintentionally by an external force, then the TV set may accidentally fall down from the hang bracket, thus damaging the TV set and even hurting a person.

### SUMMARY

Embodiments of the disclosure provide a wall-hang apparatus of a display device, and a display device so as to improve the reliability of hanging the display device on a wall securely.

An embodiment of the disclosure provides a wall-hang apparatus of a display device, the wall-hang apparatus includes: a wall fixture configured to be fixed to a wall, display device fixtures configured to be fixed to a display device body, and hang pieces, wherein the wall fixture includes first hang hooks with a notch facing upward; and the hang pieces are fixed to the display device fixtures, and include first stop blocks hung on the first hang hooks, and second stop blocks located below the first stop blocks.

In one embodiment, the display device body is fixed to the display device fixtures through fasteners, and rubber support sheaths are sleeved on the parts of the fasteners between the display device fixtures and the display device body.

In one embodiment, the wall fixture is arranged horizontally, and the display device fixtures and the hang pieces are arranged vertically.

In one embodiment, the number of hang pieces is the same as the number of display device fixtures, and at least two; and the number of first hang hooks on the wall fixture is at least two.

In one embodiment, the wall fixture includes a hang plate, and the hang pieces further include second hang hooks hung on the hang plate, and with a notch facing downward.

In one embodiment, the hang plate includes hang stop openings in which the second hang hooks are hung.

In one embodiment, the hang plate further includes hang orientation openings orientating the hang stop openings.

In the technical solutions according to the embodiments of the disclosure, the first stop blocks are hung on the first hang hooks so that the display device body to which an external force is applied away from the wall will not fall down easily from the wall-hang apparatus; and the display device body to which an external force is applied upward will not fall down easily from the wall-hang apparatus due to the second stop blocks. Thus the wall-hang apparatus of the display device according to the embodiments of the disclosure can be more secure and reliable than the prior art.

An embodiment of the disclosure further provides a display device including a display device body, and the wall-hang apparatus according to any one of the technical solutions above. The body of the display device using the wall-hang apparatus to which an external force is applied will not fall down easily from the wall-hang apparatus, so the display device can be installed highly reliably.

### BRIEF DESCRIPTION OF THE DRAWINGS

In order to make the technical solutions according to the embodiments of the disclosure or in the prior art more apparent, the drawings to which a description of the embodiments or the prior art refers will be briefly introduced below, and apparently the drawings to be described below are merely illustrative of some of the embodiments of the disclosure, and those ordinarily skilled in the art can derive from these drawings other drawings without any inventive effort. In the drawings:

FIG. 1 is a schematic diagram of a wall-hang apparatus assembled with a display device body according to an embodiment of the disclosure;

FIG. 2 is a schematic explosive view of the wall-hang apparatus according to an embodiment of the disclosure;

FIG. 3 is a schematic diagram of a hang piece according to an embodiment of the disclosure;

FIG. 4 is a schematic diagram of a wall fixture according to an embodiment of the disclosure;

FIG. 5 is a schematic diagram of the wall-hang apparatus which is hung according to an embodiment of the disclosure;

FIG. 6 is a schematic diagram of a third step of installing the wall-hang apparatus according to an embodiment of the disclosure;

FIG. 7 is a schematic diagram of a fourth step of installing the wall-hang apparatus according to an embodiment of the disclosure; and

FIG. 8 is a schematic diagram of a fifth step of installing the wall-hang apparatus according to an embodiment of the disclosure.

### REFERENCE NUMERALS

1—Wall fixture;
2—Hang piece;
3—Display device fixture;
4—Rubber support sheath;
5, 6, 7, 10—Fastener;
8—Wall;
9—Display device body;
11—First stop block;
12—First hang hook;
13—Second stop block;
14—Hang plate;
15—Second hang hook;
16—Hang stop opening;
17—Hang orientation opening.

### DETAILED DESCRIPTION OF THE EMBODIMENTS

In order to make the objects, technical solutions, and advantages of the embodiments of the disclosure more apparent, the technical solutions according to the embodiments of the disclosure will be described below clearly and fully with reference to the drawings in the embodiments of the disclosure, and apparently the embodiments described below are only a part but not all of the embodiments of the disclosure. Based upon the embodiments here of the disclosure, all the other embodiments which can occur to those skilled in the art without any inventive effort shall fall into the scope of the disclosure.

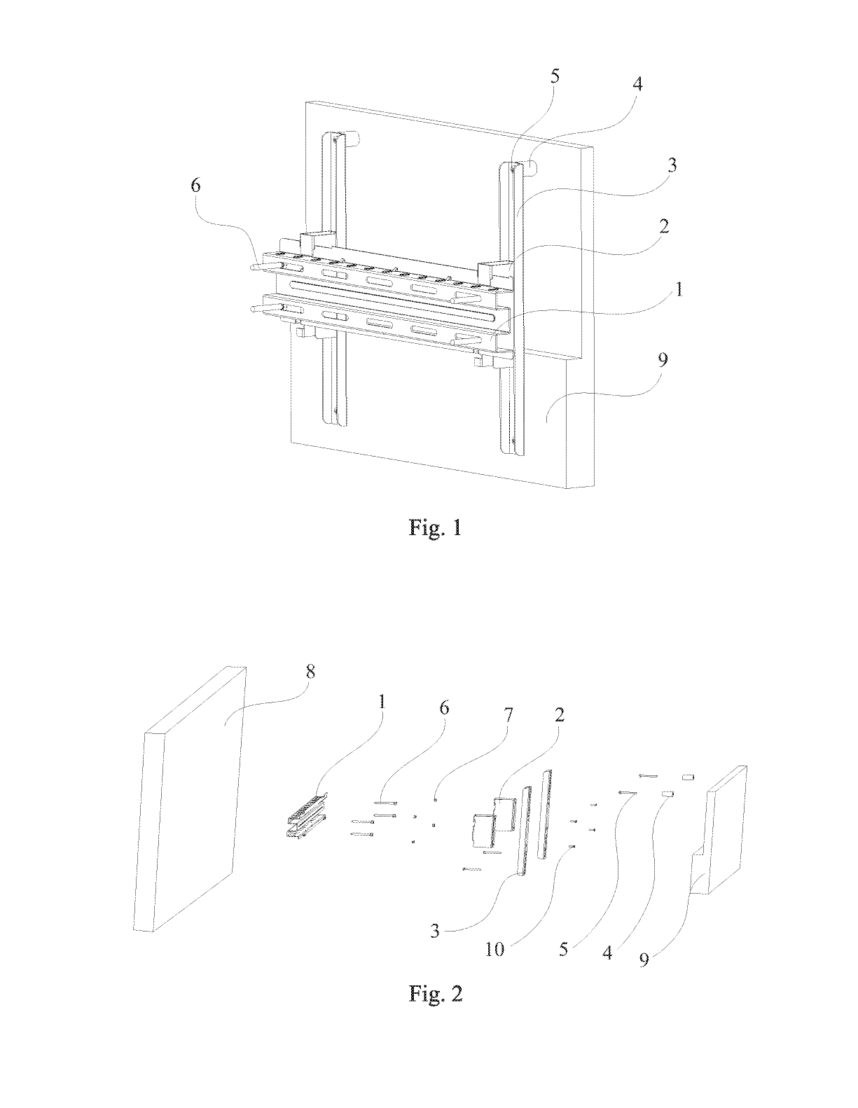

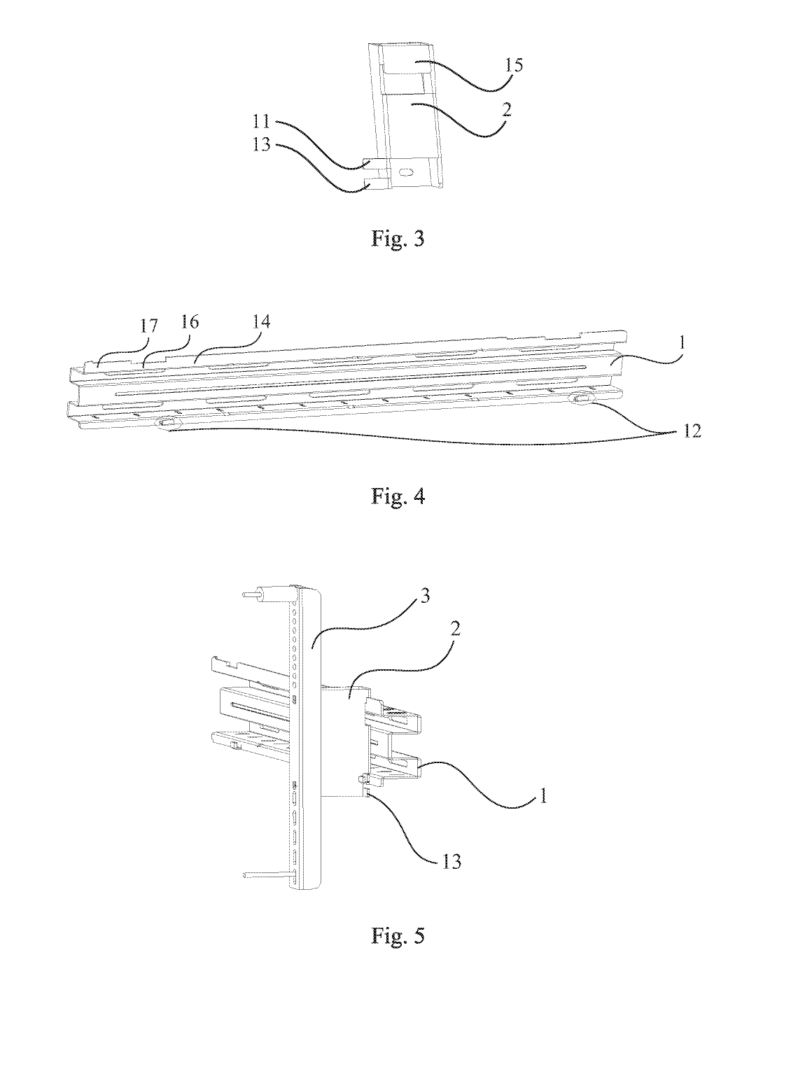

As illustrated in FIG. 1, FIG. 3, and FIG. 4, an embodiment of the disclosure provides a wall-hang apparatus of a display device, which includes a wall fixture 1 configured to be fixed to a wall 8, display device fixtures 3 configured to be fixed to a display device body, and hang pieces 2, where the wall fixture includes first hang hooks 12 with a notch facing upward; and the hang pieces 2 are fixed to the display device fixtures 3, and include first stop blocks 11 hung on the first hang hooks 12, and second stop blocks 13 located below the first stop blocks 11.

FIG. 5 is a schematic diagram of the hang-wall apparatus in which the first stop blocks are hung on the first hang hooks 12, and the second stop blocks 13 are located below the first hang hooks 12.

The wall-hang apparatus of a display device according to the embodiment of the disclosure can be applicable at home, in an office, a meeting room, an exhibition hall, a hotel, an airport, a railway station, a hospital, a bus stop, a shopping mall, and other places.

The display device body will not be limited to any particular type, but can be a TV set, a computer display, a display screen, etc., for example.

The first stop blocks are hung on the first hang hooks in the wall-hang apparatus of a display device according to the embodiment of the disclosure so that the display device body to which an external force is applied away from the wall will not fall down easily from the wall-hang apparatus; and the display device body to which an external force is applied upward will not fall down easily from the wall-hang apparatus due to the second stop blocks. Thus the wall-hang apparatus of the display device according to the embodiment of the disclosure can be more secure and reliable than the prior art.

As illustrated in FIG. 1 and FIG. 2, in a technical solution according to an embodiment of the disclosure, the display device body is fixed to the display device fixtures 3 through fasteners 5, where rubber support sheaths are sleeved on the parts of the fasteners between the display device fixtures 3 and the display device body 9. The rubber support sheath can ensure the upper and lower parts of the display device body 9 to lie on a vertical plane, and the length of the rubber support sheath can be determined on the basis of the difference in thickness between the upper and lower parts of the display device body.

As illustrated in FIG. 2, the display device fixtures 3 are fixed to the hang pieces 2 through fasteners 10, and the wall fixture 1 is fixed to the wall 8 through fasteners 6 and fasteners 7, where the fasteners 6 are bolts, and the fasteners 7 are nuts in an embodiment of the disclosure.

As illustrated in FIG. 2 , in a technical solution according to an embodiment of the disclosure, the wall fixture 1 is arranged horizontally, and the display device fixtures 3 and the hang pieces 2 are arranged vertically.

As illustrated in FIG. 1 and FIG. 4, in a technical solution according to an embodiment of the disclosure, both the numbers of hang pieces 2 and display device fixtures 3 are two; and the number of first hang hooks 12 on the wall fixture 1 is also two, which corresponds to the number of hang pieces 2. In a real application, the number of hang pieces is the same as the number of display device fixtures, but will not be limited to one or two. The number of first hang hooks on the wall fixture will not be limited to two either, but each of the first hang hooks is arranged to one corresponding hang piece.

As illustrated in FIG. 3 and FIG. 4, the wall fixture 1 includes a hang plate 14, and the hang piece 2 further includes a second hang hook 15 hung on the hang plate, and with a groove hole facing downward. The hang piece is hung on the hang plate through the second hang hook, and the hang piece is the upper end part of the wall fixture.

As illustrated in FIG. 4, in an embodiment of the disclosure, the hang plate 14 includes hang stop openings 16 in which the second hang hooks 15 are hung. The hang stop openings can stop the hang pieces in position so that the display device body to which an external force is applied in left and right direction will not fall down easily.

The hang pieces will be hung on the wall fixture by hanging the second hang hooks of the hang pieces in the hang stop openings on the hang plate of the wall fixture, and moving the first stop blocks of the hang pieces to immediately above the first hang hooks on the wall fixture. In order for precise positioning, in an embodiment of the disclosure as illustrated in FIG. 4, the hang plate 14 further includes hang orientation openings 17 orientating the hang stop openings 16. The hang plate is firstly hung in the hang orientation openings, and then moved horizontally to the hang stop openings, where the first stop blocks of the hang pieces are located immediately above the first hang hooks, and finally the hang pieces are moved downward so that the first stop openings are hung on the first hang hooks, thus finishing installation of the display device. The hang orientation openings are arranged to facilitate more convenient installation of the display device.

The display device body can be installed using the wall-hang apparatus illustrated in FIG. 1 particularly in the following steps:

The first step is to fixed the display device body to the display device fixtures through fasteners, and to fix the display device fixtures to the hang pieces through fasteners;

The second step is to fix the wall fixture to the wall through fasteners (the first step and the second step can be performed in a reversed order);

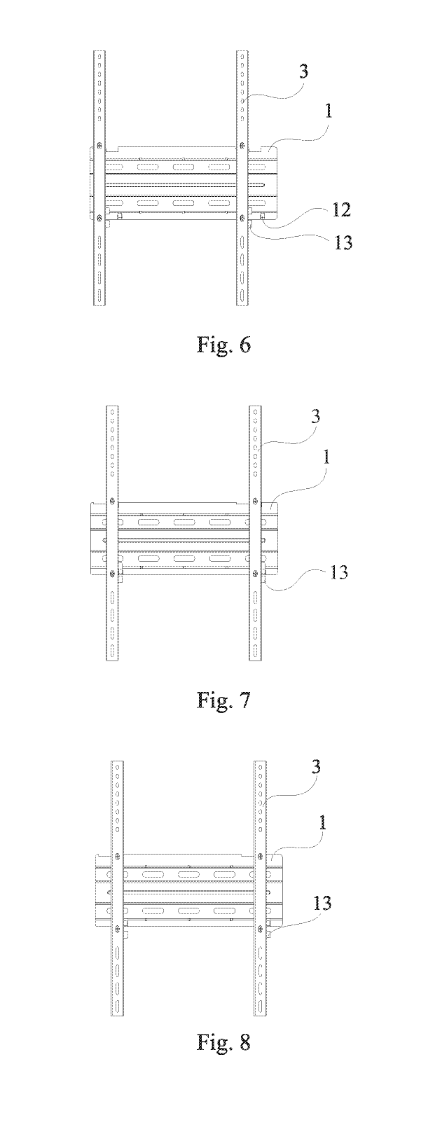

The third step is to hang the hang piece and the wall fixture in the hang orientation openings as illustrated in FIG. 6;

The fourth step is to translate the hang piece from the hang orientation openings to the hang stop openings as illustrated in FIG. 7;

The fifth step is to move downward the hang piece, and to hang the first stop blocks on the first hang hooks as illustrated in FIG. 8.

The installed wall-hang apparatus of display device is as illustrated in FIG. 1.

An embodiment of the disclosure further provides a display device including a display device body, and the wall-hang apparatus according to any one of the technical solutions above. The displaying device using the wall-hang apparatus will not fail down easily from the wall-hang apparatus even if an external force is applied thereto, so the display device can be installed highly reliably.

Lastly, it shall be noted that the respective embodiments above are merely intended to illustrate but not to limit the technical solution of the disclosure; and although the disclosure has been described above in details with reference to the embodiments above, those ordinarily skilled in the art shall appreciate that they can modify the technical solution recited in the respective embodiments above or make equivalent substitutions to a part of the technical features thereof; and these modifications or substitutions to the corresponding technical solution shall also fall into the scope of the disclosure as claimed.

1. A wall-hang apparatus of a display device, the apparatus comprises a wall fixture configured to be fixed to a wall, display device fixtures configured to be fixed to a display device body, and hang pieces, wherein:
the wall fixture comprises first hang hooks with a notch facing upward; and
the hang pieces are fixed to the display device fixtures, and comprise first stop Hocks hung on the first hang hooks, and second stop blocks located below the first stop blocks.

2. The wall-hang apparatus of a display device according to claim 1, wherein the display device body is fixed to the display device fixtures through fasteners, and rubber support sheaths are sleeved on the parts of the fasteners between the display device fixtures and the display device body.

3. The wall-hang apparatus of a display device according to claim 1, wherein the wall fixture is arranged horizontally, and the display device fixtures and the hang pieces are arranged vertically.

4. The wall-hang apparatus of a display device according to claim 1, wherein the number of hang pieces is the same as the number of display device fixtures, and at least two; and the number of first hang hooks on the wall fixture is at least two.

5. The wall-hang apparatus of a display device according to claim 1, wherein the wall fixture comprises a hang plate, and the hang pieces further comprise second hang hooks hung on the hang plate, and with a notch facing downward.

6. The wall-hang apparatus of a display device according to claim 5, wherein the hang plate comprises hang stop openings in which the second hang hooks are hung.

7. The wall-hang apparatus of a display device according to claim 6, wherein the hang plate further comprises hang orientation openings orientating the hang stop openings.

8. A display device, comprising a display device body, and a wall-hang apparatus of a display device,
wherein the wall-hang apparatus comprises a wall fixture configured to be fixed to a wall, display device fixtures configured to be fixed to a display device body, and hang pieces, wherein:
the wall fixture comprises first hang hooks with a notch facing upward; and
the hang pieces are fixed to the display device fixtures, and comprise first stop Hocks hung on the first hang hooks, and second stop blocks located below the first stop blocks.

9. The display device according to claim 8, wherein the display device body is fixed to the display device fixtures through fasteners, and rubber support sheaths are sleeved on the parts of the fasteners between the display device fixtures and the display device body.

10. The display device according to claim 8, wherein the wall fixture is arranged horizontally, and the display device fixtures and the hang pieces are arranged vertically.

11. The display device according to claim 8, wherein the number of hang pieces is the same as the number of display device fixtures, and at least two; and the number of first hang hooks on the wall fixture is at least two.

12. The display device according to claim 8, wherein the wall fixture comprises a hang plate, and the hang pieces further comprise second hang hooks hung on the hang plate, and with a notch facing downward.

13. The display device according to claim 12, wherein the hang plate comprises hang stop openings in which the second hang hooks are hung.

14. The display device according to claim 13, wherein the hang plate further comprises hang orientation openings orientating the hang stop openings.
